(19) United States
(12) Patent Application Publication
(10) Pub. No.: US 2025/0373035 A1
(43) Pub. Date: Dec. 4, 2025

(54) TRANSFORMABLE FAST CHARGER FOR WORKSITE

(71) Applicant: Caterpillar Inc., Peoria, IL (US)

(72) Inventors: Prashanth PADMANABHAN, Bangalore (IN); Prathamesh SHIVAPURI, Belagavi (IN); Andrew Blake ROBINSON, Highland, IL (US); Jeffery Andrew MOORE, Pekin, IL (US)

(73) Assignee: Caterpillar Inc., Peoria, IL (US)

(21) Appl. No.: 18/732,796

(22) Filed: Jun. 4, 2024

(51) Int. Cl. H02J 7/00; B60L 53/18; B60L 53/30

(52) U.S. Cl. CPC H02J 7/0042; B60L 53/18; B60L 53/30; B60L 2200/40; B60L 2210/10; B60L 2210/30; H02J 2207/20

(57) ABSTRACT

A configurable charger system includes a plurality of power conversion modules, wherein each power conversion module includes a power converter configured to receive an input power and convert the input power into an output power; a plurality of charger support structures, wherein each charger support structure is arranged at a base of a respective power conversion module of the plurality of power conversion modules for supporting the respective power conversion module; and a skid configured to movably support each charger support structure of the plurality of charger support structures such that each charger support structure is movable between at least two respective lateral positions, including a first respective lateral position corresponding to a respective shipping configuration and a second respective lateral position corresponding to a respective operating configuration.

### TECHNICAL FIELD

The present disclosure relates generally to a transformable charger system and, for example, to a transformable charger system that is configurable into different sized configurations.

### BACKGROUND

Chargeable loads, such as loads with rechargeable electric batteries, require periodic charging to operate. A chargeable load may include any chargeable equipment, such as an electric vehicle. Direct current (DC) power sources that can quickly charge a chargeable load may not be readily available at worksites, such as mining sites and construction sites. Thus, power conversion modules may be transported to a worksite for fast charging of chargeable loads. A power conversion module may be configured to convert alternating current (AC) power (e.g., an AC voltage) into DC power (e.g., a DC voltage) and/or convert a first DC power (e.g., a first DC voltage) into a second DC power (e.g., a second DC voltage). Thus, the power conversion module may include an AC-to-DC power converter and/or a DC-to-DC power converter.

Power conversion modules typically require transport to a worksite for use by chargeable loads. Moreover, a worksite typically requires multiple power conversion modules for charging multiple chargeable loads. In some cases, two or more power conversion modules may be used in parallel to quickly charge a single chargeable load. The power conversion modules may be heavy and bulky. As a result, the power conversion modules may require industrial equipment, such as forklifts and/or cranes, to move over short distances. Moreover, power conversion modules may be loaded into shipping containers for transport over long distances. Shipping the power conversion modules to worksites and deploying the power conversion modules at the worksites can be difficult and may incur large expenses.

U.S. Patent Publication No. 2019/0327863 (the '863 patent) discloses an improved mechanical arrangement of a drawout power module system that prevents outside contaminants from being deposited on the electronic components in the power module. The '863 patent discloses that a need exists for an improved mechanical arrangement of a power module and cabinet that would prevent the contaminants from outside of the cabinet from being deposited on the electronic components in the power module. To that end, the '863 patent discloses that an outdoor drive may include a cabinet with an air intake and an air outlet located on said cabinet and in fluid communication with an interior space of said cabinet, wherein said cabinet is configured to receive a power module within said interior space. The power module may include an environmentally sealable chamber where outside air can enter and exit only said environmentally sealable chamber of said power module. However, the '863 patent does not disclose a transformable skid assembly with supported chargers that transforms from a compact shipping configuration into an expanded operating configuration.

A configurable charger system of the present disclosure solves one or more of the problems set forth above and/or other problems in the art.

### SUMMARY

In some implementations, a configurable charger system includes a plurality of power conversion modules, wherein each power conversion module of the plurality of power conversion modules comprises a power converter configured to receive an input power and convert the input power into an output power; a plurality of charger support structures, wherein each charger support structure is arranged at a base of a respective power conversion module of the plurality of power conversion modules for supporting the respective power conversion module; and a skid configured to movably support each charger support structure of the plurality of charger support structures such that each charger support structure is movable between at least two respective lateral positions, including a first respective lateral position corresponding to a respective shipping configuration and a second respective lateral position corresponding to a respective operating configuration.

In some implementations, a configurable skid assembly includes a plurality of charger support structures, wherein each charger support structure is configured to support a respective power conversion module of a plurality of power conversion modules; and a skid configured to movably support each charger support structure of the plurality of charger support structures such that each charger support structure is movable between at least two respective lateral positions, including a first respective lateral position corresponding to a respective shipping configuration and a second respective lateral position corresponding to a respective operating configuration.

In some implementations, a method of deploying a configurable charger system includes reconfiguring the configurable charger system from a shipping configuration into an operating configuration, wherein, in the shipping configuration, a plurality of charger support structures, which support a plurality of power conversion modules, respectively, are arranged in first respective lateral positions such that the configurable charger system has a first maximum lateral dimension, and wherein, in the operating configuration, the plurality of charger support structures are arranged in second respective lateral positions such that the configurable charger system has a second maximum lateral dimension that is larger than the first maximum lateral dimension.

### BRIEF DESCRIPTION OF THE DRAWINGS

FIG. 1 is a perspective view of a configurable charger system according to one or more implementations.

FIG. 2 shows diagrams of a front view of the configurable charger system described in FIG. 1.

FIG. 3 is a side view of a configurable charger system according to one or more implementations.

FIG. 4 shows a front view of the configurable charger system described in FIG. 3.

FIG. 5 shows a front view of the configurable charger system described in FIGS. 3 and 4.

FIG. 6 shows a top view of the configurable charger system described in FIGS. 3-5, including a schematic of cable routing.

FIG. 7 is a flowchart of an example process associated with a transformable fast charger for a worksite.

### DETAILED DESCRIPTION

This disclosure relates to a configurable power conversion module system, which is applicable to any power converter device or distributed group of power converter devices that may provide output power by converting input power into the output power. The configurable power conversion module system may be configured to transform or otherwise convert from a shipping configuration into an operating configuration, or vice versa. Thus, the configurable power conversion module system may be shipped in the shipping configuration with a reduced footprint to facilitate shipping in a shipping container and handling at a worksite. The configurable power conversion module system may be deployed at the worksite by converting the configurable power conversion module system from the shipping configuration into the operating configuration, which has a larger footprint than the reduced footprint corresponding to the shipping configuration. The operating configuration may increase spacing between individual power conversion modules included in the configurable power conversion module system, which may increase accessibility to the individual power conversion modules (e.g., for servicing the individual power conversion modules), may conform to industry standards and regulations, may increase airflow to the individual power conversion modules to prevent overheating of the individual power conversion modules, and/or may increase safe operating conditions of the individual power conversion modules, which may not be otherwise possible in the shipping configuration.

The configurable power conversion module system may reduce shipping costs by reducing the footprint of the configurable power conversion module system during shipping, which may increase a number of individual power conversion modules that can be packed into a single shipping container. In addition, the configurable power conversion module system may enable faster, easier, and less complicated deployment of the individual power conversion modules at the worksite. The configurable power conversion module system may be modular and scalable in design.

The configurable power conversion module system may be a configurable charger system for charging one or more chargeable loads. For example, the individual power conversion modules may be configured to provide output power to one or more chargeable loads. The chargeable loads may be an electric battery machine, such as a vehicle, a compactor machine, a paving machine, a cold planer, a grading machine, a backhoe loader, a wheel loader, a harvester, an excavator, a motor grader, a skid steer loader, a tractor, a dozer, a hauler, or the like.

Thus, the individual power conversion modules may be closely packaged for compact shipping, with pre-assembled cables that may facilitate hookups to power sources and loads at the worksite. During deployment at the worksite, the individual power conversion modules may be converted from the shipping configuration to the operating configuration, and deployed, using a skid that may include an assembly of base rails that enable the individual power conversion modules to move laterally between respective shipping configurations (e.g., respective shipping positions) and respective operating configurations (e.g., respective operating positions). Thus, the individual power conversion modules may be spaced out when deployed.

Spacing between individual power conversion modules may be increased when deployed from the shipping configuration into the operating configuration to allow for better service access to the individual power conversion modules and to enable the individual power conversion modules to operate with safer operating conditions. For example, the skid assembly may include a walkway on a skid, which may allow for easier service access between the individual power conversion modules, enabling service access on all sides of the individual power conversion modules. The increased spacing between the individual power conversion modules when deployed into the operating configuration may allow for better air flow for cooling the individual power conversion modules. For example, the additional spacing between the individual power conversion modules may improve airflow and reduce a risk of hot air recirculating into a radiator of an adjacent power conversion module. The configurable power conversion module system may facilitate quick deployment of the individual power conversion modules at the worksite. Cables and wires and corresponding harnesses may be arranged to allow for movements of the individual power conversion modules during deployment. Moreover, power supply and isolation for the individual power conversion modules may allow for modularity and scalability.

Thus, the configurable power conversion module system may provide a compact shipping and handling footprint, an increased operating (e.g., deployed) footprint, improved serviceability and manufacturability, efficient cooling, lower cost due to modular design, and a power conversion module architecture for redundant output power.

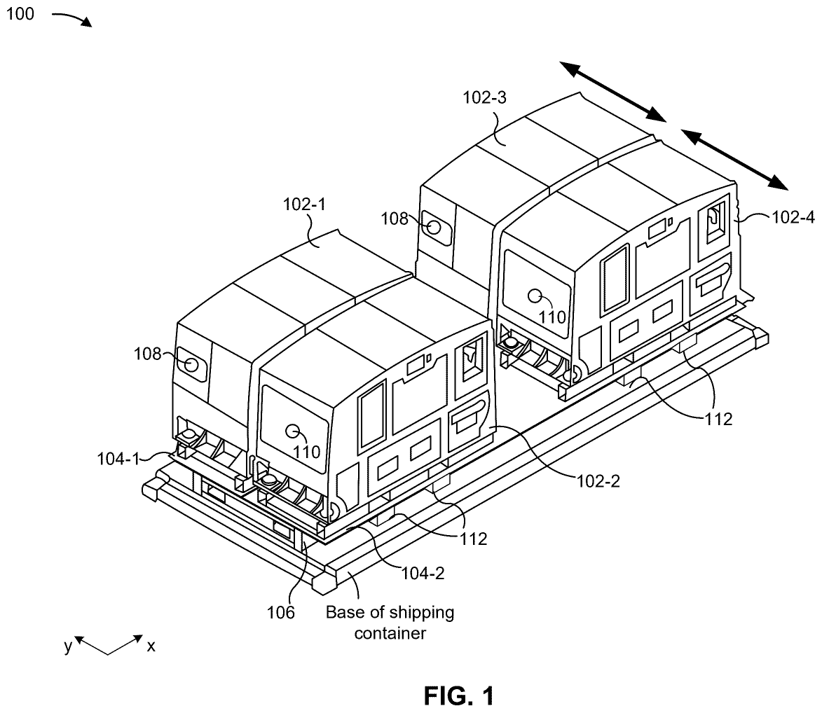

FIG. 1 is a perspective view of a configurable charger system 100 according to one or more implementations. The configurable charger system 100 includes a plurality of power conversion modules 102 (e.g., power conversion modules 102-1, 102-2, 102-3, and 102-4), a plurality of charger support structures 104 (e.g., charger support structures 104-1 and 104-2), and a skid 106. FIG. 1 shows the configurable charger system 100 configured in a shipping configuration for being transported within a shipping container. Thus, the configurable charger system 100 may be slid into the shipping container and supported on a base of the shipping container for shipping. The base of the shipping container may extend in a first lateral direction (e.g., along an x-axis) corresponding to a length dimension, and may extend in a second lateral direction (e.g., along a y-axis) corresponding to a width dimension.

Each power conversion module 102 may include at least one power converter configured to receive an input power and convert the input power into an output power. For example, each power conversion module 102 may be configured to convert AC power (e.g., an AC voltage) into DC power (e.g., a DC voltage) and/or convert a first DC power (e.g., a first DC voltage) into a second DC power (e.g., a second DC voltage). Thus, each power conversion module 102 may include an AC-to-DC power converter and/or a DC-to-DC power converter. Each power conversion module 102 may include an input power terminal 108 for receiving input power and an output power terminal 110 for supplying (e.g. outputting) output power. The input power terminal 108 and the output power terminal 110 may be cable ports or cable connectors for being coupled to respective power cables.

Each charger support structure 104 may be arranged at a base of a respective power conversion module 102 for supporting the respective power conversion module 102. Each charger support structure 104 may be movable in the second lateral direction (e.g., along a y-axis) corresponding to a width dimension of the configurable charger system 100. For example, the charger support structures 104 may be moved inward, as shown, to be arranged in the shipping configuration. Alternatively, the charger support structures 104 may be moved outward to be arranged in an operating (e.g., deployed) configuration. As the charger support structures 104 move between respective lateral positions, the power conversion modules 102 also move in the second lateral direction. For example, the charger support structures 104 may be movable platforms that support the power conversion modules 102. Thus, a footprint of the configurable charger system 100 can be changed for shipping and for deployment. In other words, the width dimension of the configurable charger system 100 can be changed to be more compact during shipping such that the width dimension of the configurable charger system 100 can fit into an interior of the shipping container. In addition, the width dimension of the configurable charger system 100 can be changed to be less compact during deployment to increase a lateral spacing between adjacent power conversion modules 102.

The skid 106 may be configured to movably support each charger support structure 104 such that each charger support structure 104 is movable between at least two respective lateral positions, including a first respective lateral position corresponding to a respective shipping configuration and a second respective lateral position corresponding to a respective operating configuration. Each first respective lateral position may correspond to a respective inward position, and each second respective lateral position may correspond to a respective outward position.

Additionally, or alternatively, each charger support structure 104 may be movable in the first lateral direction (e.g., along an x-axis) corresponding to a length dimension of the configurable charger system 100. For example, the charger support structures 104 may be moved inward along the x-axis, to be arranged in the shipping configuration. Alternatively, the charger support structures 104 may be moved outward along the x-axis to be arranged in an operating (e.g., deployed) configuration.

In some implementations, each charger support structure 104 may be movable on a diagonal (e.g., in an xy-plane) such that each charger support structure 104 moves in both lateral directions. Thus, the footprint of the configurable charger system 100 may be minimized in both lateral dimensions (e.g., width and length dimensions) for shipping and may be maximized in both lateral dimensions for operation.

The charger support structures 104 and the skid 106 may form a skid assembly that includes or more mechanisms that enable the skid 106 to movably support each charger support structure 104 such that each charger support structure 104 is movable between the at least two respective lateral positions. For example, the skid 106 may include a plurality of rails 112 that extend in the second lateral direction and that enable each charger support structure 104 to move between the at least two respective lateral positions. The rails 112 may move inward or outward in the second lateral direction to move the charger support structures 104 inward or outward, respectively. The movement of the charger support structures 104 may be manual or may be automated with a control mechanized system. For example, a cog and pully system may be used with a controller to move the charger support structures 104 between the at least two respective lateral positions.

Additionally, or alternatively, rails 112 may be used to move the charger support structures 104 inward and outward along an x-axis and/or inward and outward along a diagonal.

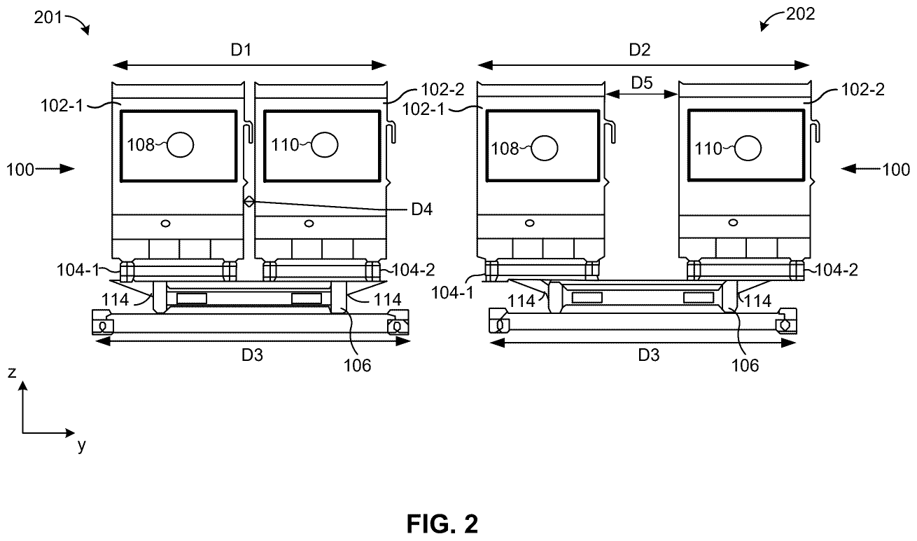

FIG. 2 shows diagrams 201 and 202 of a front view of the configurable charger system 100 described in FIG. 1. Diagram 201 shows the configurable charger system 100 in the shipping configuration in which each charger support structure 104 is arranged in the first respective lateral position corresponding to a respective shipping configuration. Diagram 202 shows the configurable charger system 100 in the operating configuration in which each charger support structures 104 is arranged in the second respective lateral position corresponding to a respective operating configuration.

The configurable charger system 100 may have a first maximum lateral dimension D1 when each charger support structure 104 is arranged in the first respective lateral position. Additionally, the configurable charger system 100 may have a second maximum lateral dimension D2 when each charger support structure 104 is arranged in the second respective lateral position. The first maximum lateral dimension D1 is smaller than the second maximum lateral dimension D2. For example, the first maximum lateral dimension D1 may be smaller than a maximum width dimension D3 of an interior of a shipping container, and the second maximum lateral dimension D2 may be larger than the maximum width dimension D3 of the interior of the shipping container.

The configurable charger system 100 may include a plurality of support locking mechanisms 114 configured to lock each charger support structure 104 into the first respective lateral position and the second respective lateral position. The plurality of support locking mechanisms 114 may be clamps or gear locking mechanisms.

The plurality of power conversion modules 102 may include a first power conversion module 102-1 and a second power conversion module 102-2 arranged relative to (e.g., adjacent to) the first power conversion module 102-1 in the second lateral direction. The first power conversion module 102-1 and the second power conversion module 102-2 may be separated by a first lateral distance D4 when the first power conversion module 102-1 and the second power conversion module 102-2 are each arranged in the first respective lateral position. The first power conversion module 102-1 and the second power conversion module 102-2 may be separated by a second lateral distance D5, that is greater than the first lateral distance D4, when the first power conversion module 102-1 and the second power conversion module 102-2 are each arranged in the second respective lateral position. Thus, the footprint of the configurable charger system 100 can be changed for shipping and for deployment. In other words, the maximum width dimension of the configurable charger system 100 can be compressed to be more compact during shipping such that the maximum width dimension of the configurable charger system 100 can fit into the interior of the shipping container. In addition, the maximum width dimension of the configurable charger system 100 can be expanded to be less compact during deployment to increase a lateral spacing between adjacent power conversion modules 102.

Thus, the configurable charger system 100 may be shipped in the shipping configuration with a reduced footprint to facilitate shipping in the shipping container and to facilitate handling at the worksite. The configurable charger system 100 may be deployed at the worksite by converting the configurable charger system 100 from the shipping configuration into the operating configuration, which has a larger footprint than the reduced footprint corresponding to the shipping configuration. The operating configuration may increase spacing between adjacent power conversion modules 102, which may increase accessibility to the individual power conversion modules (e.g., for servicing the individual power conversion modules), may conform to industry standards and regulations, may increase airflow to the individual power conversion modules to prevent overheating of the individual power conversion modules, and/or may increase safe operating conditions of the individual power conversion modules, which may not be otherwise possible in the shipping configuration.

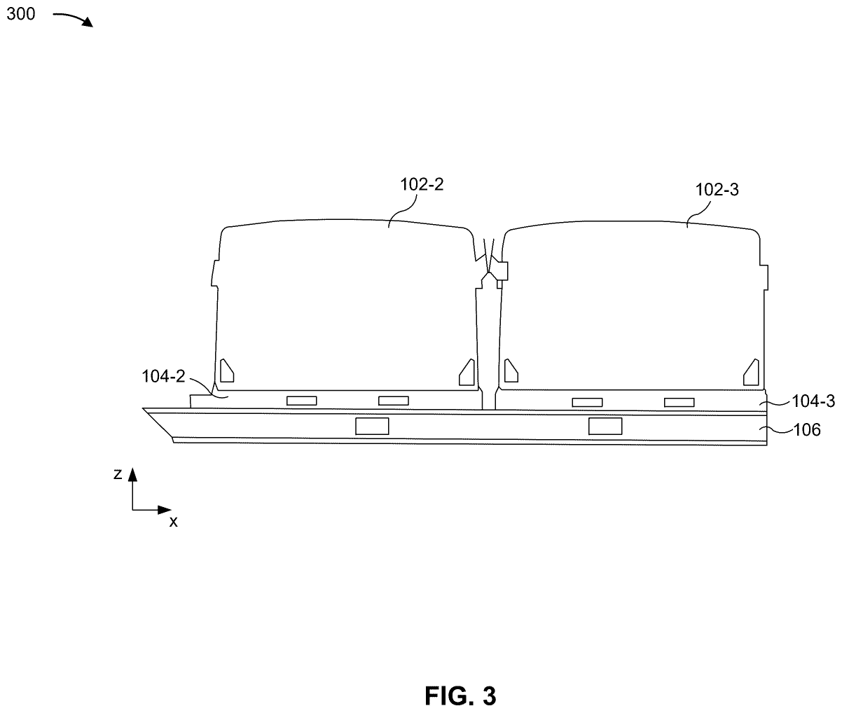

FIG. 3 is a side view of a configurable charger system 300 according to one or more implementations. The configurable charger system 300 may be similar to the configurable charger system 100. Thus, two adjacent power conversion modules 102, the second power conversion module 102-2 and a third power conversion module 102-3, are shown. Additionally, two charger support structures 104, including charger support structure 104-2 and charger support structure 104-3, are shown. The charger support structure 104-2 and the charger support structure 104-3 may be separately movable between at least two respective lateral positions, as described above. Thus, the charger support structure 104-2 and the charger support structure 104-3 may be arranged in respective shipping configurations and respective operating configurations. The charger support structure 104-2 and the charger support structure 104-3 may be movably supported by the skid 106.

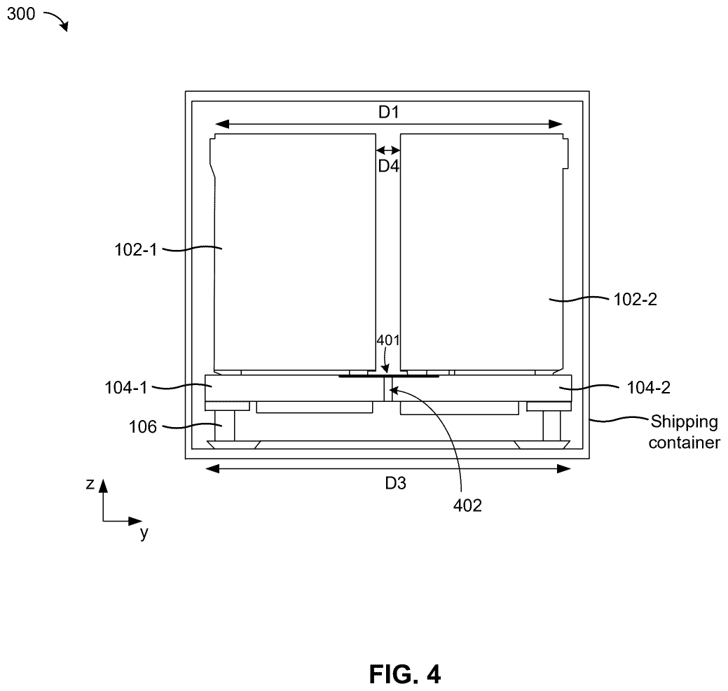

FIG. 4 shows a front view of the configurable charger system 300 described in FIG. 3. The configurable charger system 300 is arranged in a shipping configuration and is arranged inside a shipping container.

The charger support structures 104-1 and 104-2 may be movable in the second lateral direction (e.g., along a y-axis) corresponding to a width dimension of the configurable charger system 300. For example, the charger support structures 104-1 and 104-2 may be moved inward, as shown, to be arranged in the shipping configuration. Alternatively, the charger support structures 104-1 and 104-2 may be moved outward to be arranged in an operating (e.g., deployed) configuration. The charger support structures 104-1 and 104-2 may be movable platforms that support the first power conversion module 102-1 and the second power conversion module 102-2, respectively. Thus, a footprint of the configurable charger system 300 can be changed for shipping and for deployment. In other words, the maximum width dimension of the configurable charger system 300 can be changed to be more compact during shipping such that the maximum width dimension of the configurable charger system 300 can fit into an interior of the shipping container. In addition, the maximum width dimension of the configurable charger system 300 can be changed to be less compact during deployment to increase a lateral spacing between the charger support structures 104-1 and 104-2, which results in an increase in a lateral spacing between first power conversion module 102-1 and the second power conversion module 102-2.

The skid assembly may include a walkway platform 401 arranged between the first power conversion module 102-1 and the second power conversion module 102-2. The walkway platform 401 may be arranged between adjacent charger support structures (e.g., charger support structures 104-1 and 104-2). The walkway platform 401 may be arranged on top surfaces of the charger support structures 104-1 and 104-2, or may be arranged in a cavity or a volume defined by the adjacent charger support structures. For example, the walkway platform 401 may be inserted into slots of the charger support structures 104-1 and 104-2 such that most or all of the walkway platform 401 is arranged within the charger support structures 104-1 and 104-2 and/or inaccessible when the charger support structures 104-1 and 104-2 are arranged in respective shipping configurations. Thus, the walkway platform 401 may be configured to be accessible when the charger support structures 104-1 and 104-2 are arranged in the second respective lateral positions.

The skid assembly may include a trench 402 under the walkway platform 401, and a cable routing assembly (not illustrated in FIG. 4) arranged in the trench 402. The trench 402 may extend laterally within a cavity of a volume of the charger support structures 104-1 and 104-2 such that a portion of the trench 402 is not visible or accessible when the charger support structures 104-1 and 104-2 are arranged in respective shipping configurations. A lateral dimension of the trench 402 may change based on the first charger support structure 104-1 and the second charger support structure 104-2 being in first respective lateral positions or the second respective lateral positions. Additionally, the cable routing assembly may be arranged in the portion of the trench 402 that is not visible or accessible when the charger support structures 104-1 and 104-2 are arranged in respective shipping configurations.

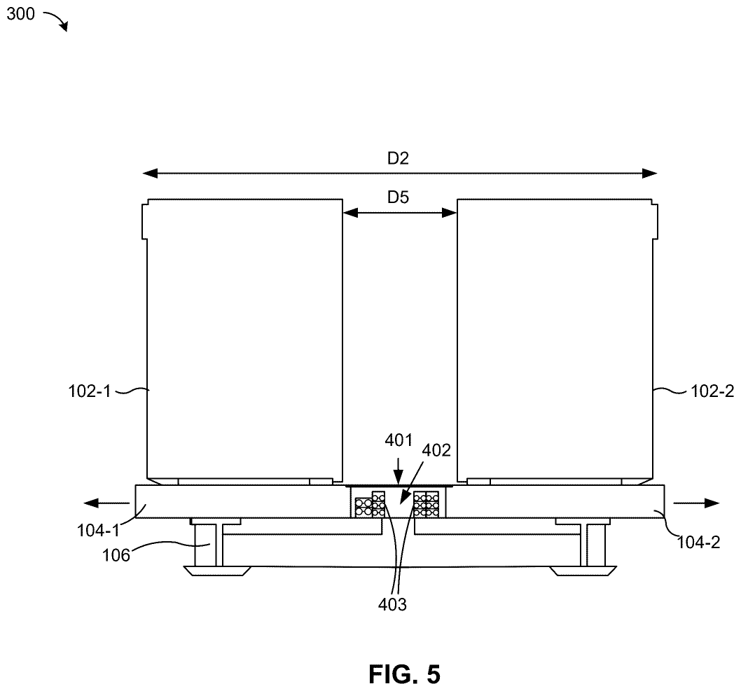

FIG. 5 shows a front view of the configurable charger system 300 described in FIGS. 3 and 4. The configurable charger system 300 is arranged in an operating (e.g., deployed) configuration and is arranged outside of a shipping container. The lateral distances between the charger support structures 104-1 and 104-2, and between the first power conversion module 102-1 and the second power conversion module 102-2, have been increased relative to the configurable charger system 300 shown in FIG. 4. As a result, the maximum width dimension of the configurable charger system 300 has also been increased.

The walkway platform 401 may now be accessible to service personnel such that the service personnel can walk between the first power conversion module 102-1 and the second power conversion module 102-2.

In addition, a cable routing assembly 403 is visible and may be accessible. The cable routing assembly 403 may include cable glands and/or grommets for cable routing. The configurable charger system 300 may include a plurality of input power cables, a plurality of output power cables, and one or more communication cables that are routed through the cable routing assembly 403. Each input power cable may be coupled to a respective power source and a respective power conversion module 102 for providing the input power to the respective power conversion module 102. Each output power cable may be coupled to a respective power conversion module 102 for receiving output power from the respective power conversion module 102 and providing the output power to a respective power output. The respective power output may be coupled to one or more loads, such as one or more charging loads. The plurality of input power cables, the plurality of output power cables, and the one or more communication cables may be preassembled (e.g., prior to shipping), including being connected to the input power terminals 108 and the output power terminals 110 of respective power conversion modules 102 to facilitate deployment at the worksite. Cables, wires, and corresponding harnesses may be arranged to allow for movements of the power conversion modules 102 during deployment.

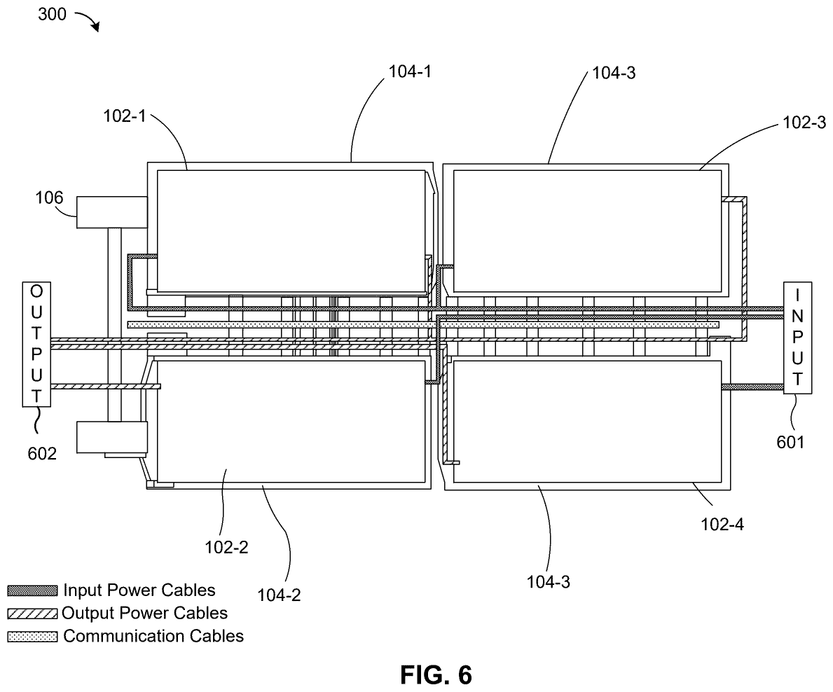

FIG. 6 shows a top view of the configurable charger system 300 described in FIGS. 3-5, including a schematic of cable routing. The walkway platform 401 has been omitted in order to show the trench 402, the cable routing assembly 403, and the cables.

Each input power cable may be coupled to a respective power source 601 and a respective power conversion module 102 for providing the input power to the respective power conversion module 102. Each output power cable may be coupled to a respective power conversion module 102 for receiving output power from the respective power conversion module 102 and providing the output power to a respective power output 602. The respective power output 602 may be coupled to one or more loads, such as one or more charging loads.

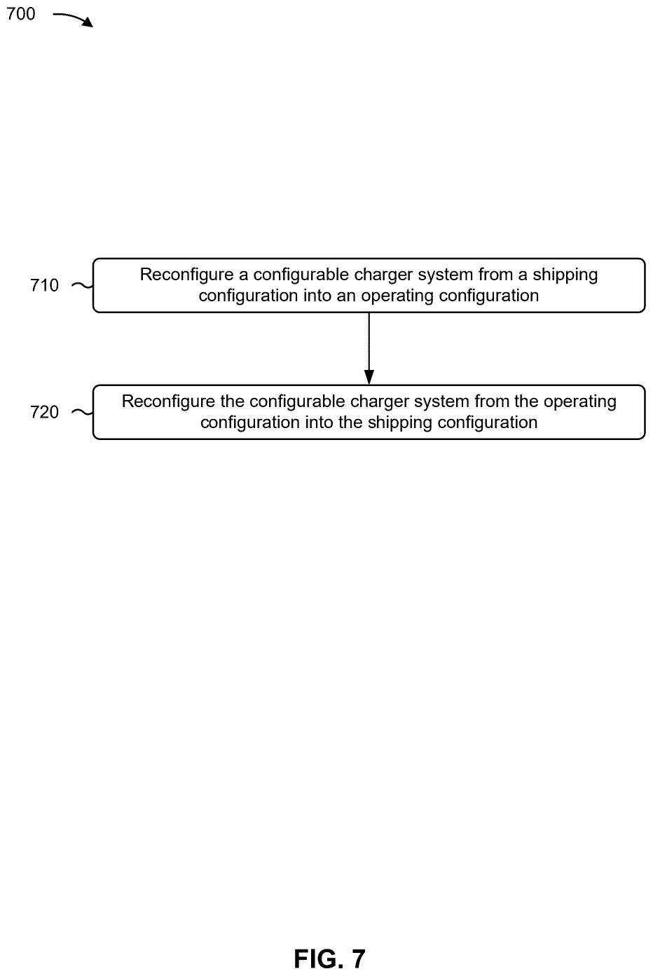

FIG. 7 is a flowchart of an example process 700 associated with a transformable fast charger for a worksite. One or more process blocks of FIG. 7 may be performed by a configurable charger system (e.g., configurable charger system 100 or configurable charger system 300).

As shown in FIG. 7, process 700 may include reconfiguring the configurable charger system from a shipping configuration into an operating configuration (block 710). In the shipping configuration, a plurality of charger support structures, which support a plurality of power conversion modules, respectively, are arranged in first respective lateral positions such that the configurable charger system has a first maximum lateral dimension. In the operating configuration, the plurality of charger support structures are arranged in second respective lateral positions such that the configurable charger system has a second maximum lateral dimension that is larger than the first maximum lateral dimension. In addition, the process 700 may include reconfiguring the configurable charger system from the operating configuration into the shipping configuration (block 720).

Each first respective lateral position of the first respective lateral positions corresponds to a respective inward position, and each second respective lateral position of the second respective lateral positions corresponds to a respective outward position.

Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

### INDUSTRIAL APPLICABILITY

A configurable power conversion module system, such as a configurable charger system, may be configured to transform or otherwise convert from a shipping configuration into an operating configuration, or vice versa. Thus, the configurable power conversion module system may be shipped in the shipping configuration with a reduced footprint to facilitate shipping in a shipping container and handling at a worksite. The configurable power conversion module system may be deployed at the worksite by converting the configurable power conversion module system from the shipping configuration into the operating configuration, which has a larger footprint than the reduced footprint corresponding to the shipping configuration. The operating configuration may increase spacing between individual power conversion modules included in the configurable power conversion module system, which may increase accessibility to the individual power conversion modules (e.g., for servicing the individual power conversion modules), may conform to industry standards and regulations, may increase airflow to the individual power conversion modules to prevent overheating of the individual power conversion modules, and/or may increase safe operating conditions of the individual power conversion modules, which may not be otherwise possible in the shipping configuration.

What is claimed is:

1. A configurable charger system, comprising:
a plurality of power conversion modules, wherein each power conversion module of the plurality of power conversion modules comprises a power converter configured to receive an input power and convert the input power into an output power;
a plurality of charger support structures, wherein each charger support structure is arranged at a base of a respective power conversion module of the plurality of power conversion modules for supporting the respective power conversion module; and
a skid configured to movably support each charger support structure of the plurality of charger support structures such that each charger support structure is movable between at least two respective lateral positions, including a first respective lateral position corresponding to a respective shipping configuration and a second respective lateral position corresponding to a respective operating configuration.

2. The configurable charger system of claim 1, wherein the skid includes a plurality of rails that extend in a lateral direction that enable each charger support structure to move between the at least two respective lateral positions.

3. The configurable charger system of claim 1, wherein the plurality of charger support structures are movable platforms.

4. The configurable charger system of claim 1, wherein each first respective lateral position corresponds to a respective inward position, and each second respective lateral position corresponds to a respective outward position.

5. The configurable charger system of claim 1, wherein the configurable charger system has a first maximum lateral dimension when each charger support structure is arranged in the first respective lateral position,
wherein the configurable charger system has a second maximum lateral dimension when each charger support structure is arranged in the second respective lateral position, and
wherein the first maximum lateral dimension is smaller than the second maximum lateral dimension.

6. The configurable charger system of claim 5, wherein the first maximum lateral dimension is smaller than a maximum width dimension of an interior of a shipping container, and
wherein the second maximum lateral dimension is larger than the maximum width dimension of the interior of the shipping container.

7. The configurable charger system of claim 1, wherein the plurality of power conversion modules includes a first power conversion module and a second power conversion module arranged relative to the first power conversion module in a lateral direction,
wherein the first power conversion module and the second power conversion module are separated by a first lateral distance when the first power conversion module and the second power conversion module are each arranged in the first respective lateral position, and
wherein the first power conversion module and the second power conversion module are separated by a second lateral distance, that is greater than the first lateral distance, when the first power conversion module and the second power conversion module are each arranged in the second respective lateral position.

8. The configurable charger system of claim 7, wherein the skid includes a walkway platform arranged between the first power conversion module and the second power conversion, and
wherein the walkway platform is configured to be accessible when the first power conversion module and the second power conversion module are each arranged in the second respective lateral position.

9. The configurable charger system of claim 8, wherein the skid includes a trench under the walkway platform, and a cable routing assembly arranged in the trench.

10. The configurable charger system of claim 9, further comprising:
a plurality of input power cables, wherein each input power cable of the plurality of input power cables is coupled to a respective power source and a respective power conversion module for providing the input power to the respective power conversion module; and
a plurality of output power cables, wherein each output power cable of the plurality of output power cables is coupled to a respective power conversion module for providing the output power to a respective power output,
wherein the plurality of input power cables and the plurality of output power cables are routed through the cable routing assembly.

11. A configurable skid assembly, comprising:
a plurality of charger support structures, wherein each charger support structure is configured to support a respective power conversion module of a plurality of power conversion modules; and
a skid configured to movably support each charger support structure of the plurality of charger support structures such that each charger support structure is movable between at least two respective lateral positions, including a first respective lateral position corresponding to a respective shipping configuration and a second respective lateral position corresponding to a respective operating configuration.

12. The configurable skid assembly of claim 11, wherein the plurality of charger support structures are movable platforms mechanically coupled to the skid.

13. The configurable skid assembly of claim 11, wherein each first respective lateral position corresponds to a respective inward position, and each second respective lateral position corresponds to a respective outward position.

14. The configurable skid assembly of claim 11, wherein the configurable skid assembly has a first maximum lateral dimension when each charger support structure is arranged in the first respective lateral position,
wherein the configurable skid assembly has a second maximum lateral dimension when each charger support structure is arranged in the second respective lateral position, and
wherein the first maximum lateral dimension is smaller than the second maximum lateral dimension.

15. The configurable skid assembly of claim 14, wherein the first maximum lateral dimension is smaller than a maximum width dimension of an interior of a shipping container, and
wherein the second maximum lateral dimension is larger than the maximum width dimension of the interior of the shipping container.

16. The configurable skid assembly of claim 11, wherein the plurality of charger support structures includes a first charger support structure and a second charger support structure arranged relative to the first charger support structure in a lateral direction,
wherein the first charger support structure and the second charger support structure are separated by a first lateral distance when the first charger support structure and the second charger support structure are each arranged in the first respective lateral position, and
wherein the first charger support structure and the second charger support structure are separated by a second lateral distance, that is greater than the first lateral distance, when the first charger support structure and the second charger support structure are each arranged in the second respective lateral position.

17. The configurable skid assembly of claim 16, further comprising:
a trench arranged laterally between the first charger support structure and the second charger support structure, wherein a lateral dimension of the trench changes based on the first charger support structure and the second charger support structure being in the first respective lateral position or the second respective lateral position;
a cable routing assembly arranged in the trench;
a plurality of power cables routed through the cable routing assembly; and
a walkway platform arranged over the trench, wherein the walkway platform is configured to be accessible when the first charger support structure and the second charger support structure are each arranged in the second respective lateral position.

18. The configurable skid assembly of claim 11, further comprising:
a plurality of support locking mechanisms configured to lock each charger support structure of the plurality of charger support structures into the first respective lateral position and the second respective lateral position.

19. A method of deploying a configurable charger system, the method comprising:
reconfiguring the configurable charger system from a shipping configuration into an operating configuration,
wherein, in the shipping configuration, a plurality of charger support structures, which support a plurality of power conversion modules, respectively, are arranged in first respective lateral positions such that the configurable charger system has a first maximum lateral dimension, and
wherein, in the operating configuration, the plurality of charger support structures are arranged in second respective lateral positions such that the configurable charger system has a second maximum lateral dimension that is larger than the first maximum lateral dimension.

20. The method of claim 19, wherein each first respective lateral position of the first respective lateral positions corresponds to a respective inward position, and each second respective lateral position of the second respective lateral positions corresponds to a respective outward position.
